(19) United States
(12) Patent Application Publication
(10) Pub. No.: US 2005/0135075 A1
(43) Pub. Date: Jun. 23, 2005

(54) Computer case and parts thereof

(75) Inventor: Xiao Gan Deng, Guangdong (CN)

Correspondence Address: BURNS DOANE SWECKER & MATHIS L L P, POST OFFICE BOX 1404, ALEXANDRIA, VA, 22313-1404, US

(73) Assignee: E. com Compucase Co., Ltd., Tortola (VG)

(21) Appl. No.: 10/872,396

(22) Filed: Jun. 22, 2004

Related U.S. Application Data
(63) Continuation-in-part of application No. 29/197,737, filed on Jan. 21, 2004, now Pat. No. D499096.

(30) Foreign Application Priority Data
Dec. 23, 2003 (CN) 2003201299056

(51) Int. Cl. H05K 7/14

(52) U.S. Cl. 361/797

(57) ABSTRACT

A panel which may be fastened to a side, top or bottom of or formed integrally with a computer case comprising a body member defining an outwardly facing surface and an inwardly facing surface, wherein the body member is provided with at least one conglomerate of apertures, and an area defined by a perimeter of the conglomerate of apertures is at least substantially 50% of the area of the body member.

### FIELD OF THE INVENTION

The present invention relates to a computer, a computer case and/or parts thereof.

### BACKGROUND OF THE INVENTION

There are a variety of computers and computer cases for housing the computers. As computer technologies advance, computing power in many computers and computer systems including personal computers accordingly increases their power drastically. However, one drawback is that an enormous amount of heat is generated from different components (e.g. CPUs) in such computers during their operation. In order to maintain a lower temperature in a computer, an extraction or ventilation fan is normally provided within the computer case of a computer such that warm air in the computer case is blown out therefrom and replaced with cooler ambient air from outside. One disadvantage with the provision of a fan is that it necessarily consumes electricity and it in itself also generates heat during its operation. In addition, much noise is also generated, this is particularly so due to the normally relatively small fan size and its high speed of rotation. Yet, even with the provision of a fan within a computer case, the temperature can still be substantially higher than the ambient air temperature. In extreme cases, it has been reported that computers can actually catch fire due to the elevated temperature therein and cause serious injuries to users and property damages. Although it has been proposed that one or more powerful fans may be used seeking to effectively lower the interior temperature of a computer, this would often only undesirably increase the noise generated by the fans. As there is a growing demand for computers that are more compact in size, have high computing speed and have more components that generate heat, using more fans or more powerful fans may not be practical.

### OBJECT OF THE INVENTION

It is thus the object of the present invention to provide a computer, a compute case or parts thereof for addressing the above problem, or at least to provide a useful alternative to the public.

### SUMMARY OF THE INVENTION

According to a first aspect of the present invention, there is provided a panel which may be fastened to a side, top or bottom of or formed integrally with a computer case comprising a body member defining an outwardly facing surface and an inwardly facing surface, wherein the body member is provided with at least one conglomerate of apertures, and an area defined by a perimeter of the conglomerate of apertures is at least substantially 50% of the area of the body member. Preferably, the area defined by the perimeter of the conglomerate of apertures is substantially 50% to 90% of the area of the body member. The shape of the area of the conglomerate of apertures may be rectangular, although any other shape suitable for facilitating ventilation and for performing an aesthetic function may be used.

According to a second aspect of the present invention, there is provided a panel which may be secured to a side or top of or formed integrally with a computer case comprising a generally flat and relatively thin body member defining an outwardly facing surface and an inwardly facing surface, wherein the body member is provided with a plurality of apertures, the total area of the apertures is at least substantially 6% or more of the area of the body member. Preferably, the total area may be substantially 6% to 17% of the area of the body member.

A computer case with panels as described above is particularly suitable for use on personal computers since there is often a higher requirement on quite operation of personal computers.

The panel preferably provides at least 1500 of the apertures for facilitating ventilation. Experiments have indicated that computer cases having such a panel can effectively allow sufficient ventilation.

The body member may preferably be generally flat and relatively thin.

The panel may preferably be an exterior panel.

Preferably, any or each of the apertures may be of a width of at least substantially 0.1 cm, although it may be of a width of from substantially 0.1 cm to 1 cm. The average width of the apertures may also be at least substantially 0.1 cm, although it may often be from substantially 0.1 cm to 1 cm.

Preferably, the body member may be provided with a marginal area arranged at a peripheral area thereof and the marginal area may be substantially free of apertures. Alternatively, the apertures may be evenly distributed on the panel without any marginal area.

Experiments have shown that the apertures having one or more of the above characteristics facilitates ventilation and cooling of components in a computer and ensure that the panel can provide any structural support needed to the computer case or the computer. If, for example, the size and/or the number of the apertures, and/or the area of the conglomerate of apertures exceeds a certain limit, then the structural integrity of the computer case or the computer may be compromised unless a stronger material (which is necessarily more costly and thus not practical) is used for making the panel or the computer case. If however the size and/or the number of the apertures, and/or the area of the conglomerate of apertures is not sufficient, then there would be inadequate ventilation and/or cooling provided. Experiments have shown that if too many apertures are provided or the apertures are too large then excessive radiation would be emitted via the apertures of the computer case of the computer and such radiation can undesirably interfere with the surroundings, e.g. surrounding electronic devices or medical devices.

Suitably, the panel may be a side panel or a top panel, although the panel may also be a front panel, a rear panel, or a bottom panel.

Advantageously, the aperture may be of circular, triangular, square, rhombus or star shape. The shape of the apertures and the arrangement of the apertures may also contribute to the ventilation to the computer and/or structural integrity of the computer case.

Preferably, the panel may further comprise a fastening means for fastening itself to a computer case.

Preferably, the panel may further comprises a securing means to which a filtering means may be secured. The securing means may comprise a retaining frame for retaining the filtering means, and the retaining frame may be of substantially inverted L-shape. There may be provided with two such retaining frames in the panel, such as at opposite sides of the panel.

Alternatively, the securing means may comprise a retaining channel for retaining the filtering means. The retaining channel may be of substantially inverted L-shape. The retaining channel may be an elongate channel.

According to a third aspect of the present invention, there is provided a computer comprising a panel as described above. The computer case may further comprise a frame to which the panel may be secured. The computer case may comprise three of the panels, which may be top, left side and right side panels, respectively.

Preferably, the computer case may comprise a filtering means adapted to filter air entering the interior of the computer case via the apertures of the panel. The presence of the filtering means may often important especially in an area where it is dusty. The building up of dust in the interior of a computer case and the heating up of the dust during operation of the computer by various components in the computer could cause the computer to catch fire.

Preferably, the filtering means may be securable to the inwardly facing surface of the panel. Alternatively, the filtering means may be securable to the frame.

It is to be noted that interior of the computer case is fluid communicable with the exterior of the computer case via the apertures and/or the filtering means. The presence of the apertures and the filtering creates a synergy where the various components in the computer can be cooled down naturally and environmentally by ambient air and yet dust cannot easily enter the interior of the computer case.

While the front of a computer case normally does not require a panel as described above, a panel having a similar design as the side or top panel may be provided and the panel may be securable to a front cover of the computer case for the sake of consistency.

The computer case may preferably be provided with a handle means for carrying thereof. In particular, the computer case may be provided with two handles at the top and two handles at the bottom thereof.

According to a fourth aspect of the present invention, there is provided a computer comprising a computer case as described above.

### BRIEF DESCRIPTION OF THE DRAWINGS

Embodiments of the present invention are now described, by way of examples only, with reference to the following drawings in which:—

FIG. 1 is a front perspective view of a computer case in accordance with a first embodiment of the present invention, with a faceplate and a decorative panel assembly detached from the computer case;

FIG. 2 is an exploded view of the computer case shown in FIG. 1;

FIG. 3 is a front perspective view of a computer case in accordance with a second embodiment of the present invention;

FIGS. 4 to 9 are a top view, a bottom view, a left side view, a right side view, a front view and a rear view, respectively, of the computer case shown in FIG. 3;

FIG. 10 is an enlarged front perspective showing a top corner of the computer case shown in FIG. 3;

FIG. 11 is a front perspective view of a computer case in accordance with a third embodiment of the present invention;

FIG. 12 is an enlarged front perspective showing a top corner of the computer case shown in FIG. 11;

FIG. 13 is a front perspective view of a computer case in accordance with a fourth embodiment of the present invention;

FIG. 14 is an enlarged front perspective showing a top corner of the computer case shown in FIG. 11;

FIG. 15 is a front perspective view of a computer case in accordance with a fifth embodiment of the present invention;

FIG. 16 is an enlarged front perspective showing a top corner of the computer case shown in FIG. 15;

FIG. 17 is a front perspective view of a computer case in accordance with a sixth embodiment of the present invention; and

FIG. 18 is a front perspective view of a computer case in accordance with a seventh embodiment of the present invention.

### DETAILED DESCRIPTION OF PREFERRED EMBOIMENTS OF THE PRESENT INVENTION

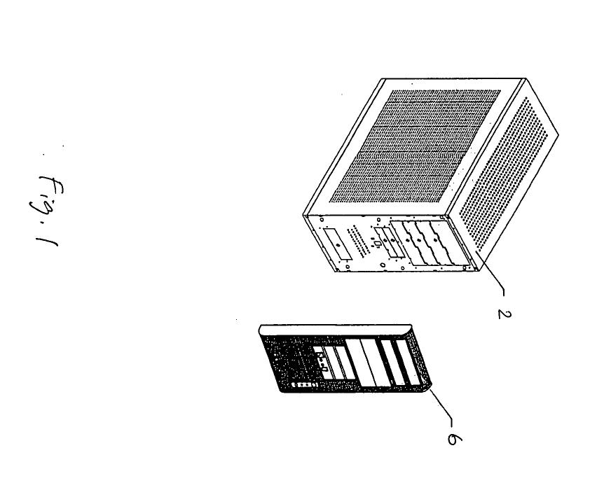

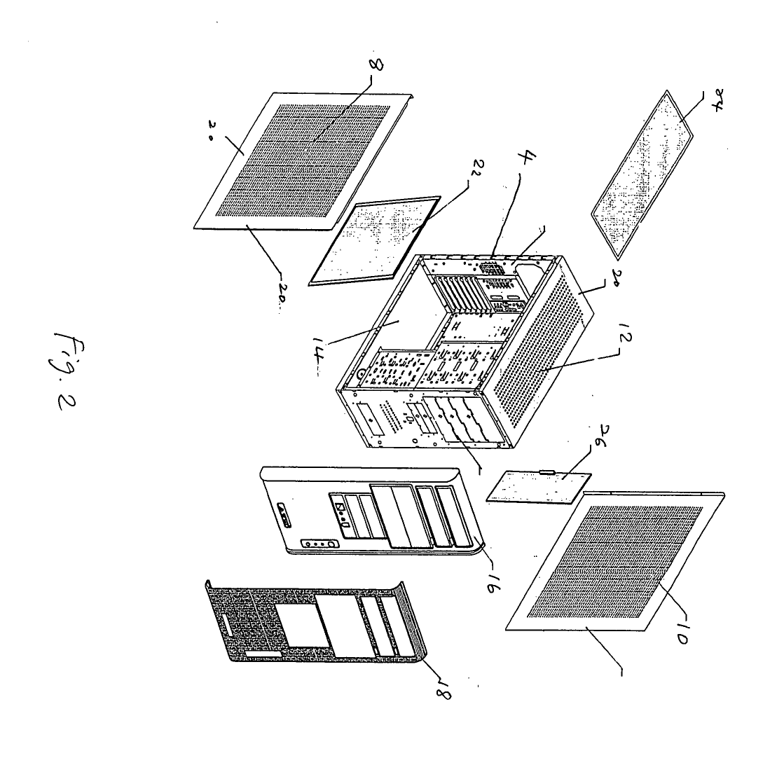

Referring firstly to FIGS. 1 to 2, there is shown schematically a novel computer case 2 of a computer in accordance with a first embodiment of the present invention. The case 2 comprises a frame 4 to which a front cover assembly 6 and a plurality of panels (or cover plates) including a left side panel 8, a right side panel 10, a top panel 12 and a bottom panel 14 are securable. The front cover assembly 6 comprises a conventional faceplate 16 of a computer case and a decorative panel 18 attachable to the faceplate 16. Each of the panels 8, 10, 12, 14 is substantially planar and provides an inwardly facing surface and an outwardly facing surface.

The two side panels 8, 10 and the top panel 12 are provided with a plurality of apertures, and on each of the panels (8, 10 or 12) the apertures are generally arranged at the middle portion thereof such that there is a peripheral region or marginal area 20 of the panel where there is no aperture. The front panel 18 is generally similar to the side and top panels 8, 10, 12 in that there is provided with a plurality of similar apertures. The appearance of the front panel 18 is thus aesthetically consistent with the side and top panels 8, 10, 12.

As shown in FIGS. 1 and 2, the apertures on each of the side and top panels 8, 10, 12 are arranged together in one large aperture conglomerate of a rectangular shape. In this embodiment, the area of the aperture conglomerate of the top panel 12 is about 60% and that of each of the left and right side panels 8, 10 is about 57%. However, experiments have shown that in practice the area of the aperture conglomerate on a panel may be at least about 50%, or range from about 50% to 90%, and a satisfactory ventilation will still be obtainable. The area of aperture conglomerate refers to the area defined by the perimeter of the aperture conglomerate. In other words, the area of the aperture conglomerate is about the area of the panel minus the area of the peripheral area of the panel where there is no aperture.

In this embodiment, the area of the apertures together on the top panel 12 is about 6% of the size thereof, and the area of the apertures together on any of side panels 8, 10 is about 17%. However, in practice experiments have shown that the area of the apertures together may range from substantially 6% to 17% of the size of that panel.

In this embodiment, at least 1500 of the apertures are provided on each of the top and side panels. It is to be noted that the feature concerning the area of aperture conglomerate, the area of apertures together on a particular panel and the number of apertures on a particular panel are different ways for defining the requirement of the present invention and they are not only not mutually exclusive but in many cases they could co-exist in a computer case in accordance with the present invention.

In this embodiment, the apertures are of substantially same size and each aperture has a width of about 0.25 mm although experiments have shown that the width of each aperture, or the average width of the apertures may range from about 0.1 cm to 1 cm.

The computer case 2 may also be provided with a number of filters 22, 24, 26 which are installed adjacent to the inwardly facing surface of the panels. Both the panels and the filters may be securable to the frame of the computer case. In this embodiment, each of the panels may be provided with at least two retaining frames which are of inverted L-shape, and the relevant filter may be retained at the retaining frames. Alternatively, the panels may be provided with an elongate retaining channel, and the filter may be removably and/or repeatedly inserted to the channel. The filter may be removable for cleaning and maintenance purposes.

Experiments have shown that with the use of a computer case as described above, the temperature of the interior of a typical operating computer can be lowered by at least 1° C.

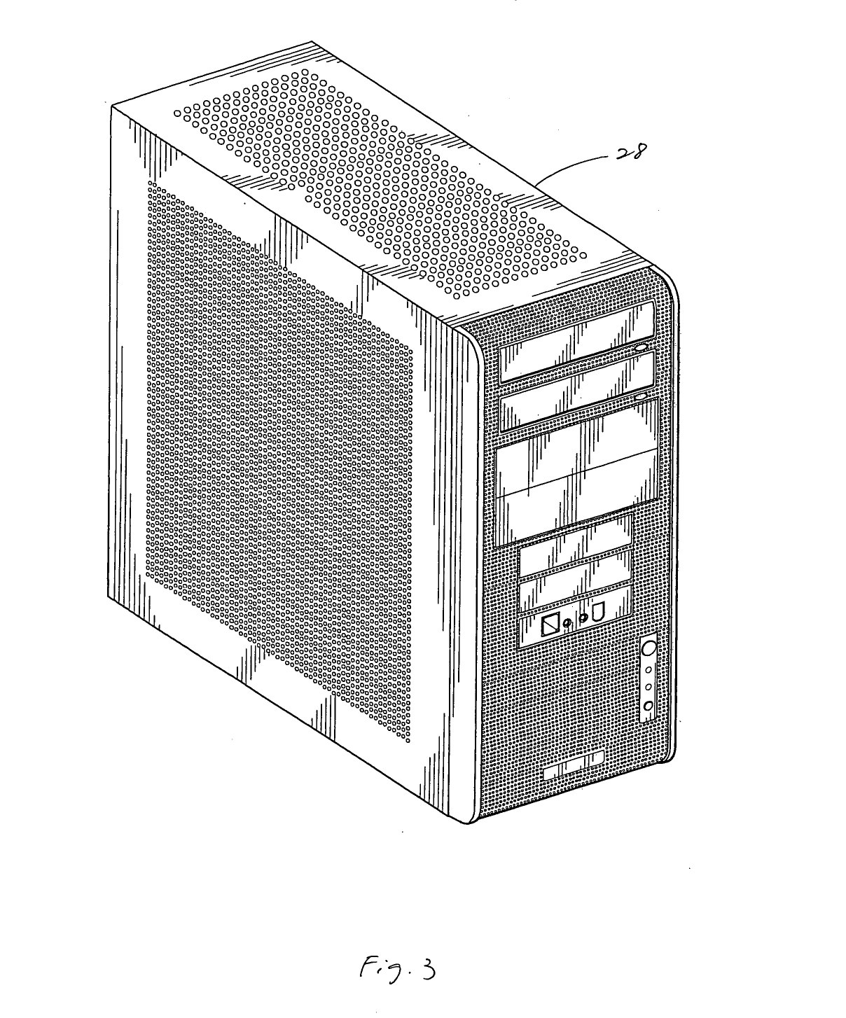

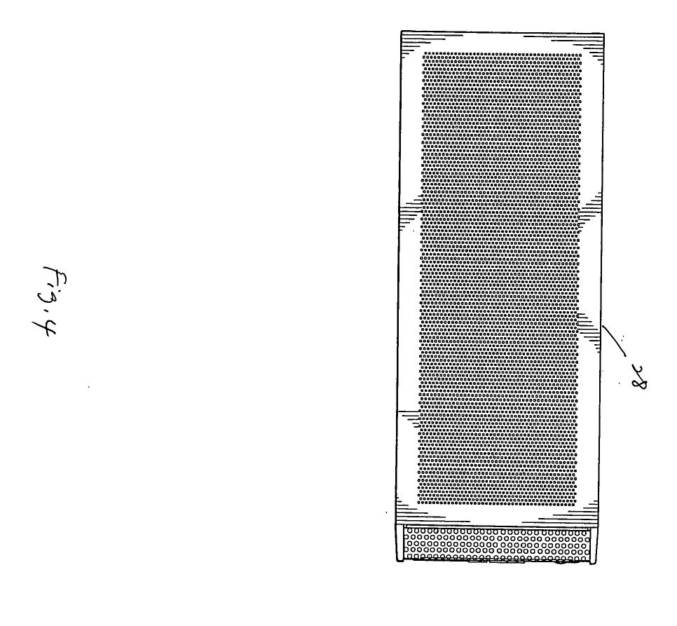

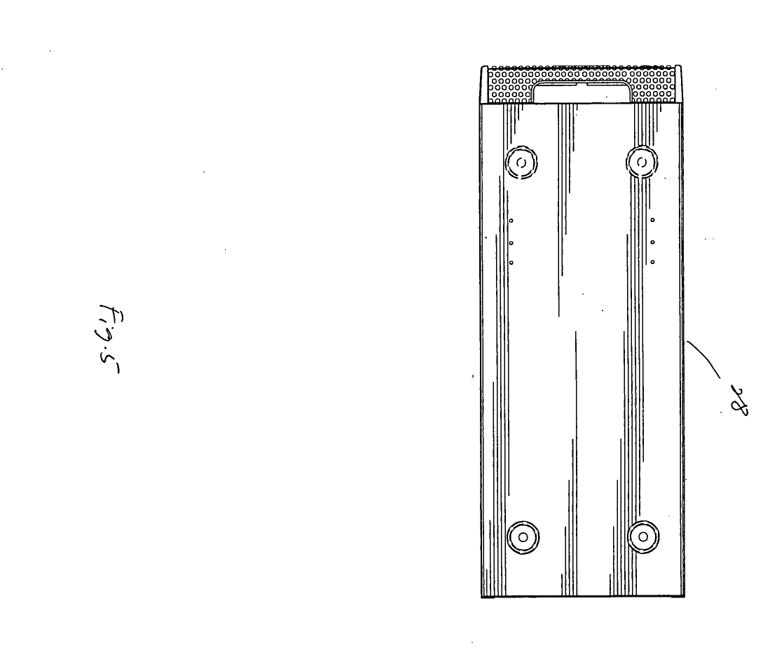

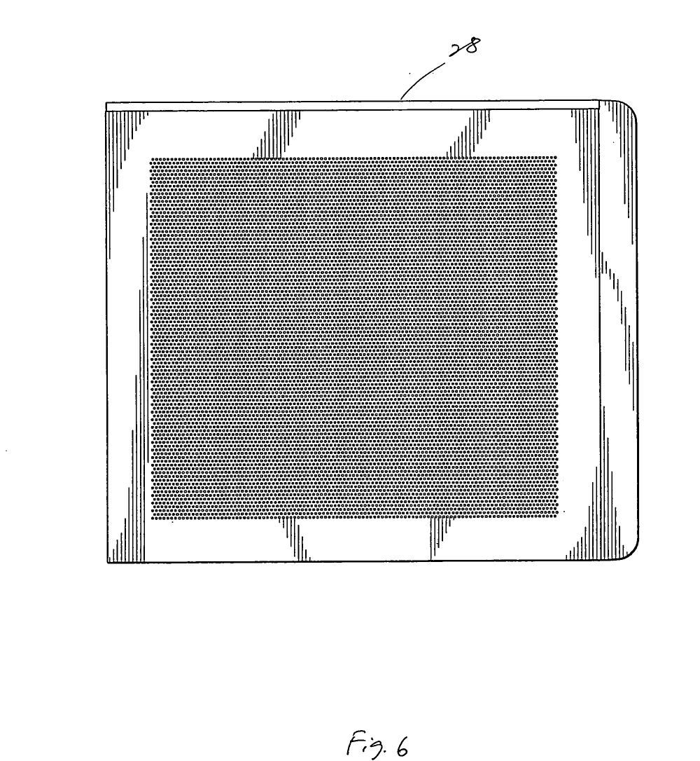

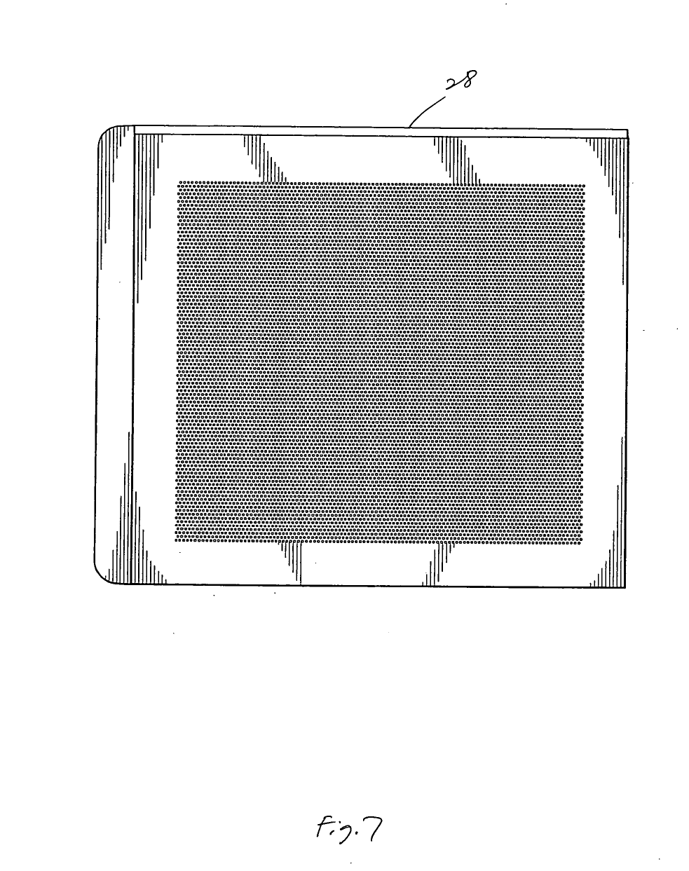

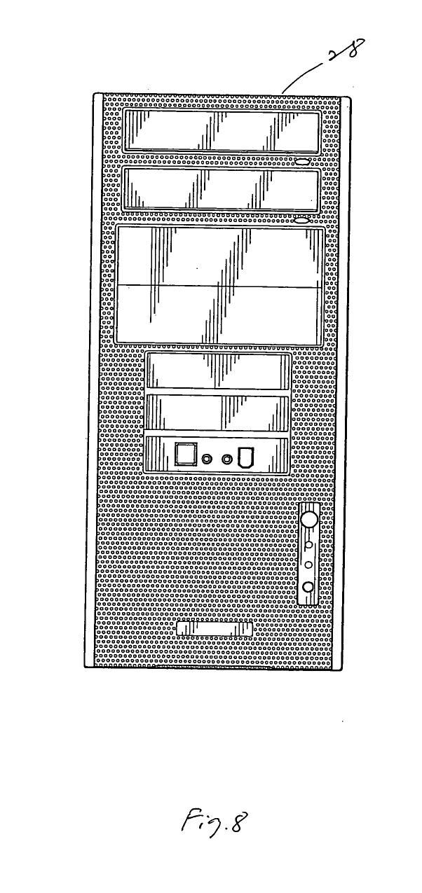

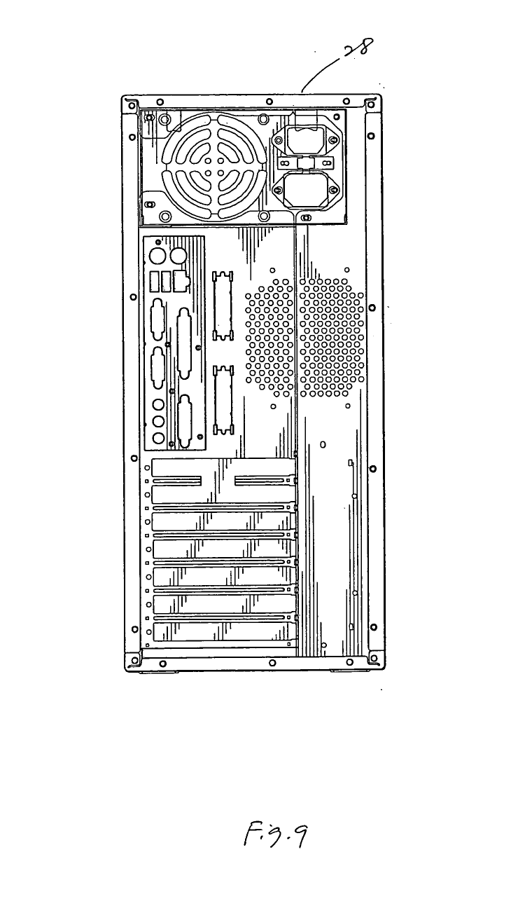

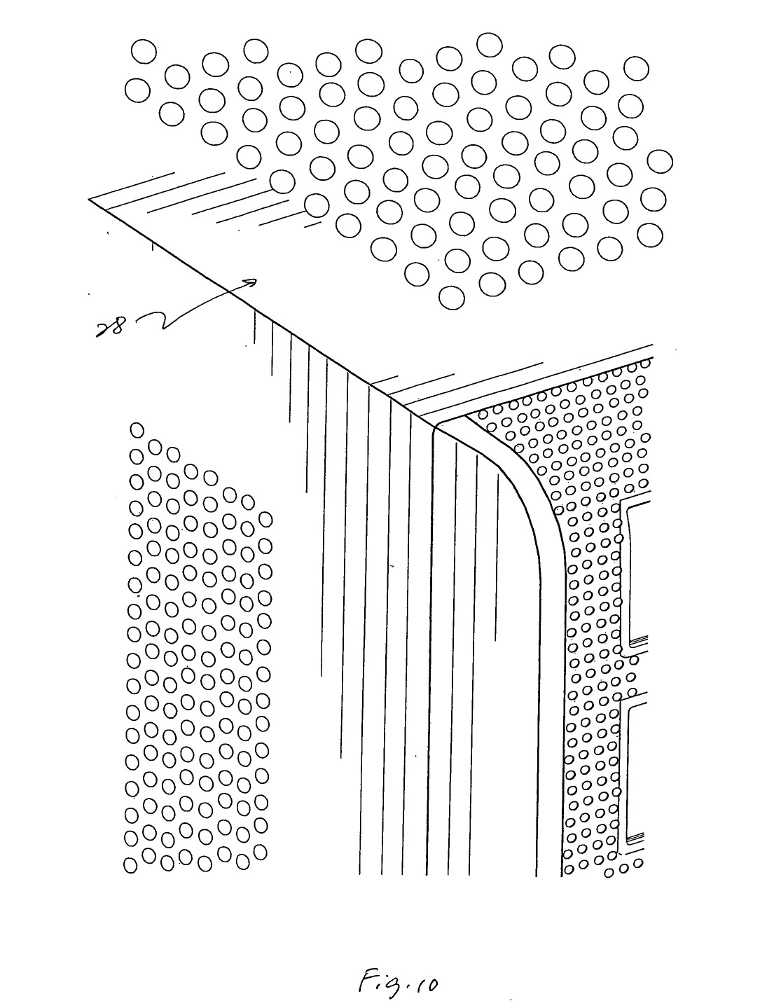

FIGS. 3 to 10 show a computer case 28 in accordance with a second aspect of the present invention. It is to be noted that similar to the shape of the aperture on the panels in the first embodiment, the shape in this embodiment is circular.

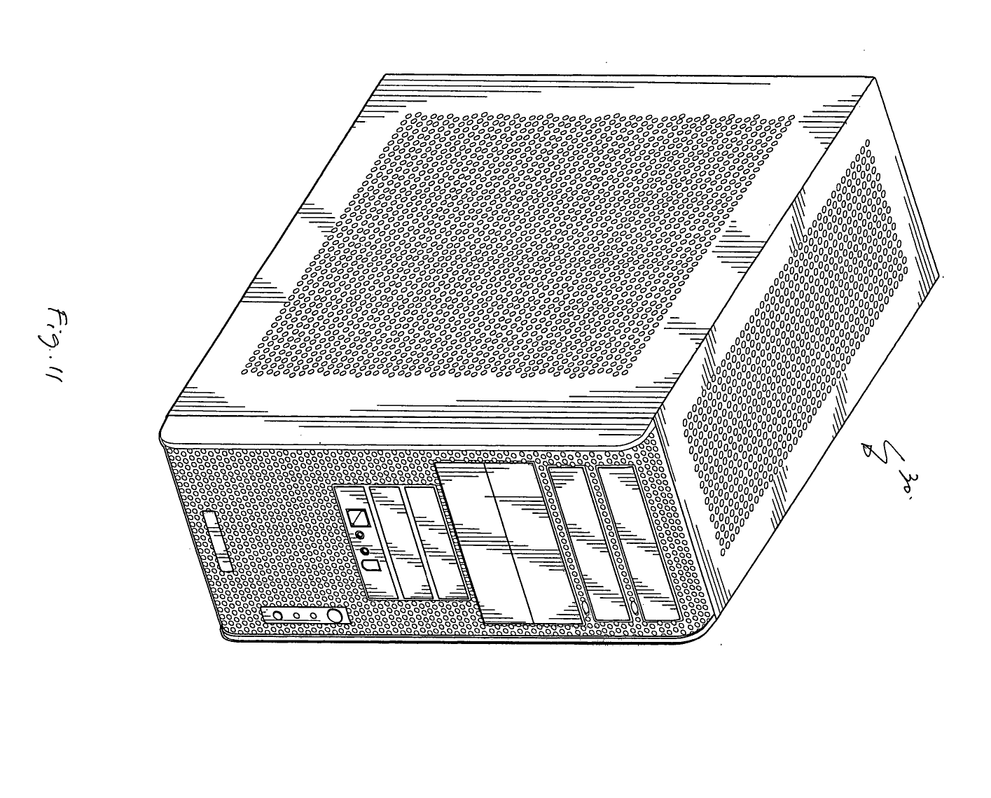

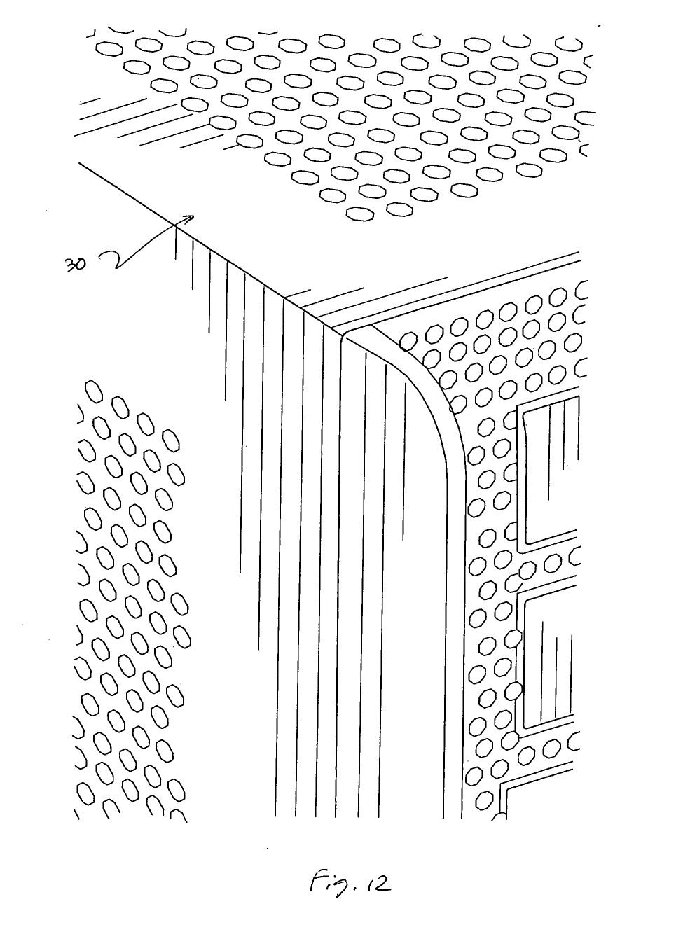

FIGS. 11 to 12 show a computer 30 case in accordance with a third aspect of the present invention. It is to be noted that the shape of each of the apertures is polygonal.

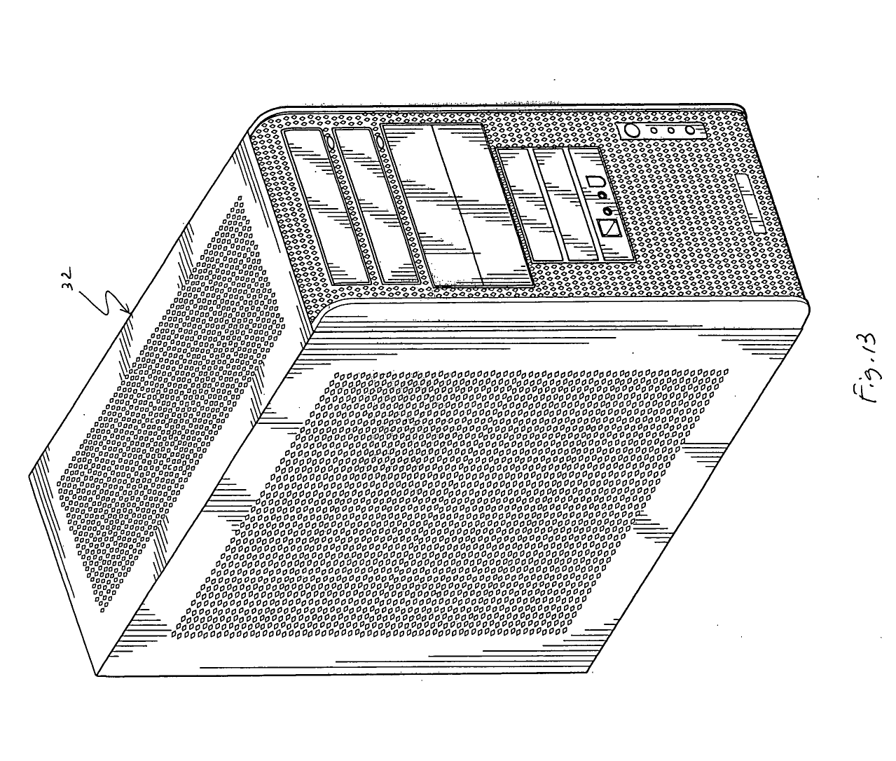

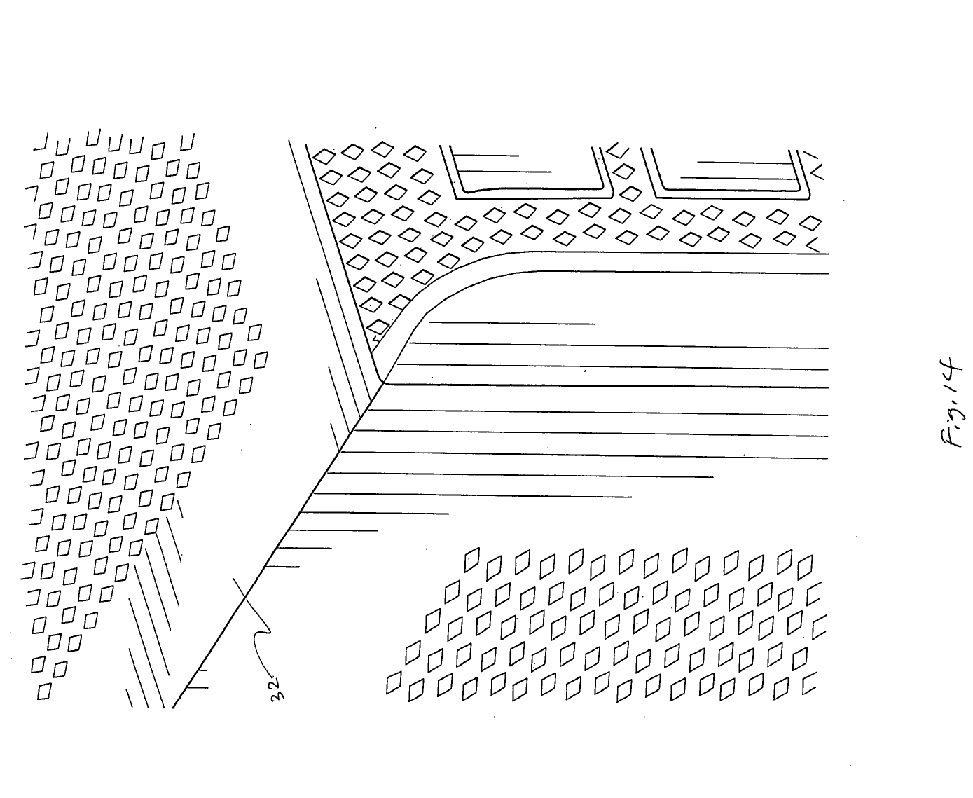

FIGS. 13 to 14 show a computer case 32 in accordance with a fourth aspect of the present invention. It is to be noted that the shape of each of the apertures is rhombus.

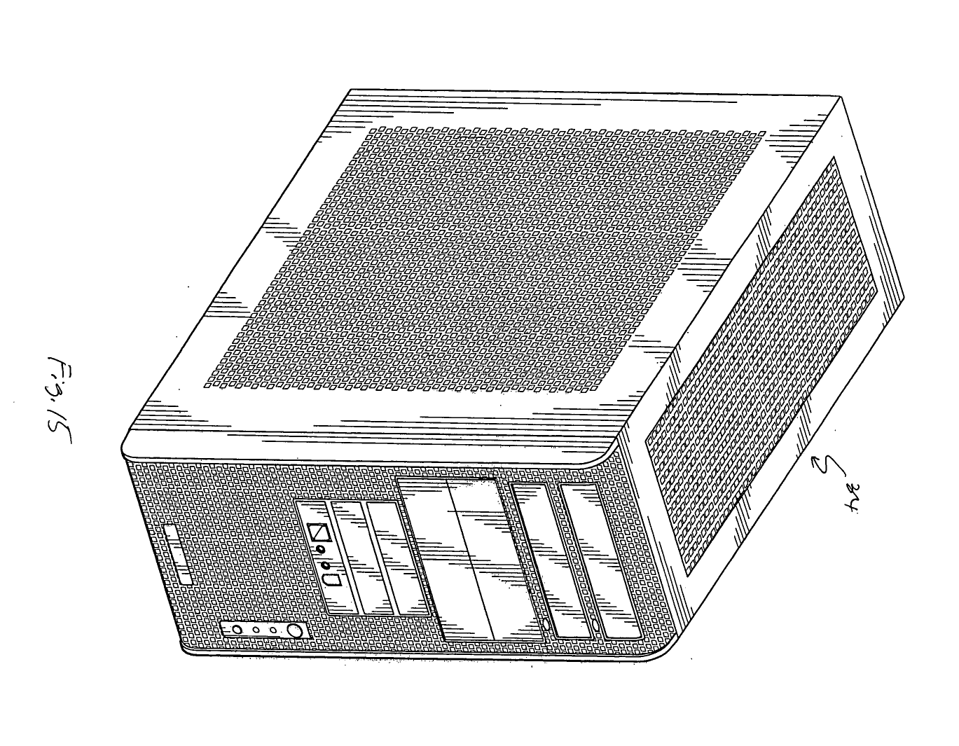

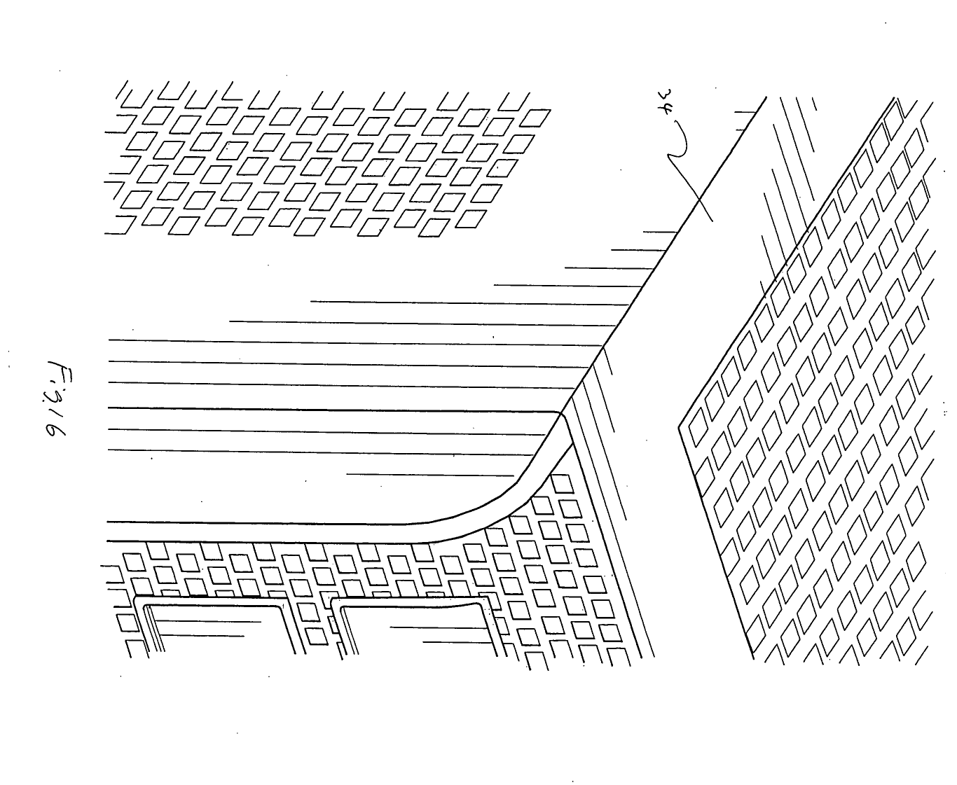

FIGS. 15 to 16 show a computer case 34 in accordance with a fifth aspect of the present invention. It is to be noted that the shape of each of the apertures is square.

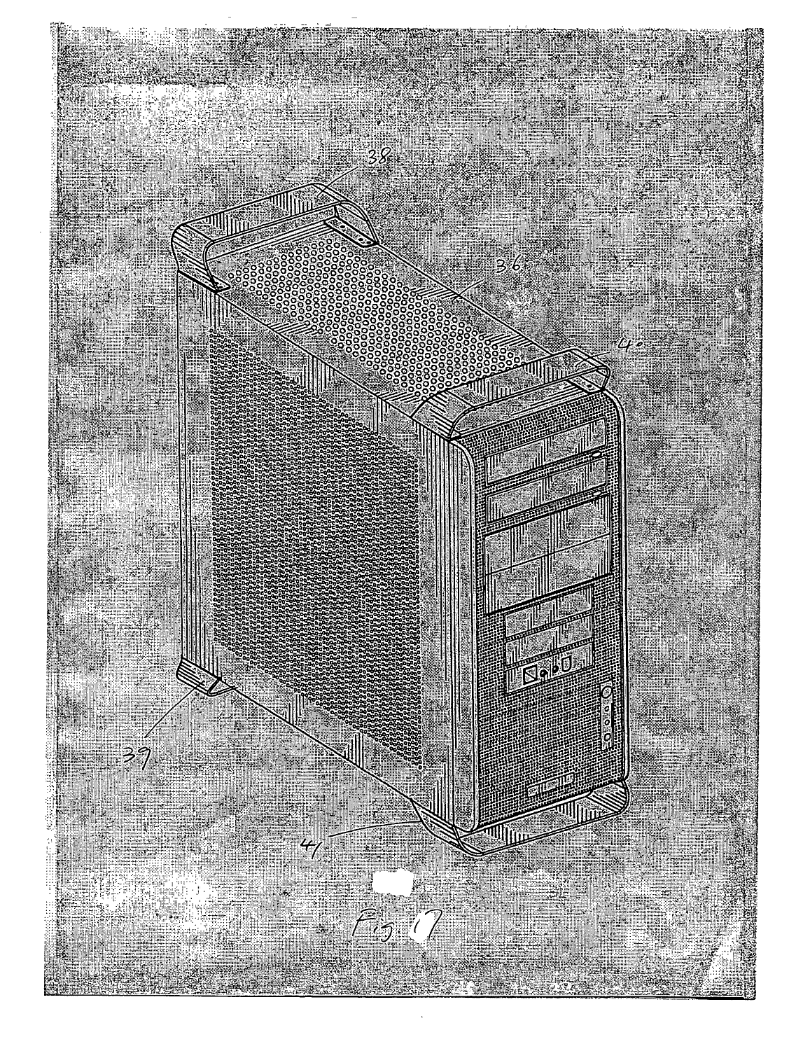

FIG. 17 shows a computer case 36 in accordance with a sixth aspect of the present invention. It is to be noted that the computer case is provided with two handles 38, 40 at its top. Two further handles 39, 41 are provided at its bottom.

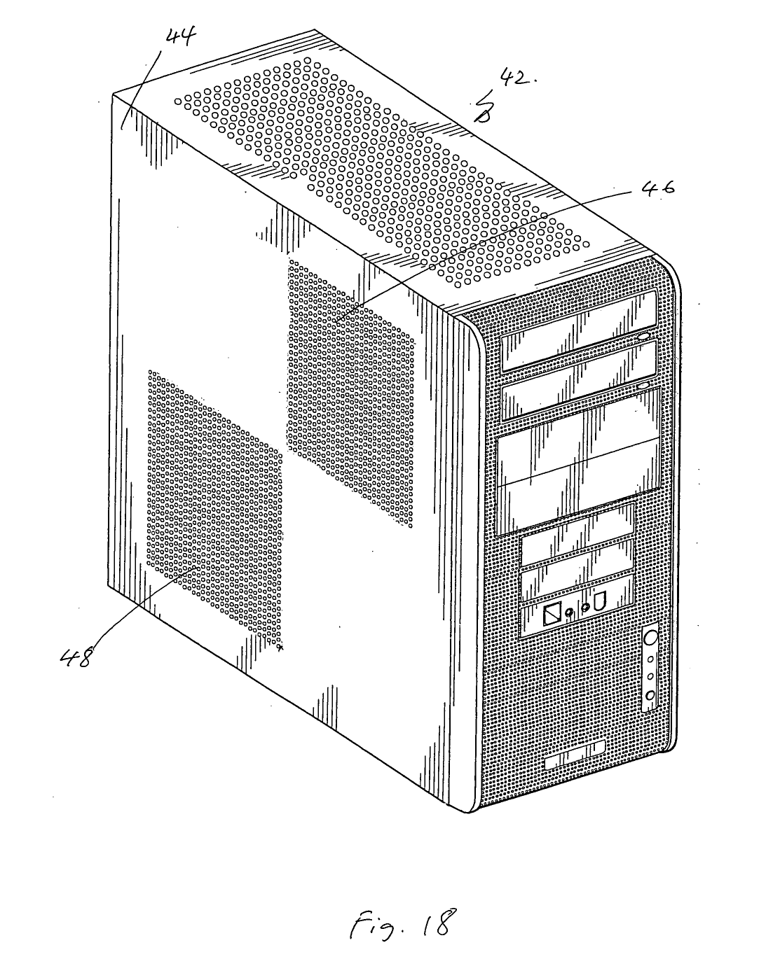

FIG. 18 shows a computer case 42 in accordance with a seventh aspect of the present invention. It is to be noted that the side panel 44 is provided with two conglomerates of apertures with a first conglomerate 46 thereof in rectangular shape arranged at the upper right side thereof and a second conglomerate 48 thereof also in rectangular shape arranged at the lower left side thereof. The location of the conglomerates of apertures is tailored made to match the location of heating generating components in the interior of a computer having such a computer case. For instance, if the CPU of a computer is located at the lower rear side of a tower desktop computer, the provision of a conglomerate of apertures at a lower left side of the left panel of the computer case thereof will maximize ventilation of the CPU area and facilitate cooling of the CPU. Depending on the location of various heat generating components in the computer case, one or more conglomerates of apertures can be provided on the computer case to maximize cooling efficiency of the components. In practice, the shape of the conglomerates of apertures may also differ and be adapted to suit particular needs of ventilation.

It is thus envisaged that the presence of the apertures on the panels provides an apparatus or method which has a technical advantage for providing ventilation to the computer. It is to be noted that no electricity is consumed with by such ventilating or cooling method, and thus it is environmentally friendly.

In the past, accessing to the interior of a conventional computer is often very difficult and cumbersome. It is to be noted that the panels and/or the filters of a computer in accordance with the presence invention may be repeatedly removable from the computer case easily and conveniently such that access to the components for maintenance or cleaning is made much easier by simply removing one or more of the panels of filters therefrom.

1. A panel which may be fastened to a side, top or bottom of or formed integrally with a computer case comprising a body member defining an outwardly facing surface and an inwardly facing surface, wherein said body member is provided with at least one conglomerate of apertures, and an area defined by a perimeter of said conglomerate of apertures is at least substantially 50% of the area of the outwardly or inwardly facing surface of said body member.

2. A panel as claimed in claim 1 wherein said area defined by the perimeter of said conglomerate of apertures is substantially 50% to 90% of the area of said body member.

3. A panel which may be secured to a side or top of or formed integrally with a computer case comprising a body member defining an outwardly facing surface and an inwardly facing surface, wherein said body member is provided with a plurality of apertures, the total area of the apertures is a least substantially 6% of the area of the outwardly or inwardly facing surface of said body member.

4. A panel as claimed in claim 1 or 3 providing at least 1500 said apertures.

5. A panel as claimed in claim 1 or 3 wherein said body member is generally flat and/or relatively thin.

6. A panel as claimed in claim 1 or 3 wherein any or each of said apertures is of a width of 0.1 to 1 cm.

7. A panel as claimed in claim 1 or 3 wherein the average size of said apertures is about 0.1 to 1 cm.

8. A panel as claimed in claim 1 or 3 wherein said body member is provided with a marginal area arranged at a peripheral area thereof and said marginal area is substantially free of apertures.

9. A panel as claimed in claim 1 or 3 wherein said panel is a side panel.

10. A panel as claimed in claim 1 or 3 wherein said panel is a top panel.

11. A panel as claimed in claim 1 or 3 wherein said aperture is a circular, triangular, square rhombus or star shape.

12. A panel as claimed in claim 1 or 3 comprising a fastening means for fastening itself to a computer case.

13. A panel as claimed in claim 1 or 3 comprising a securing means to which a filtering means may be secured.

14. A panel as claimed in claim 13 wherein said securing means comprised a retaining frame for retaining said filtering means.

15. A panel as claimed in claim 13 wherein said retaining frame is of substantially inverted L-shape.

16. A panel as claimed in claim 14 comprising two said retaining frames.

17. A panel as claimed in claim 13 wherein said securing means comprises a retaining channel for retaining said filter means.

18. A panel as claimed in claim 17 wherein said retaining channel is of substantially inverted L-shape.

19. A panel as claimed in claim 17 wherein said retaining channel is an elongate channel.

20. A computer case comprising a panel as claimed in claim 3.

21. A computer case as claimed in claim 20 comprising a frame to which said panel may be secured.

22. A computer case as claimed in claim 20 comprising three said panels.

23. A computer case as claimed in claim 21 comprising a filtering means.

24. A computer case as claimed in claim 22 wherein said filtering means is securable to said inwardly facing surface of said panel.

25. A computer case as claimed in claim 23 wherein said filtering means is securable to said frame.

26. A computer case as claimed in claim 20 wherein the interior of said computer case is fluid communicable with the exterior of said computer case via said apertures and/or said filtering means.

27. A computer case as claimed in claim 20 comprising a panel securable to a front cover thereof.

28. A computer case as claimed in claim 20 comprising a handle means.

29. A computer comprising a computer case as claimed in claim 20.

30. A computer case comprising a panel as claimed in claim 1.

31. A computer case as claimed in claim 30 comprising a frame to which said panel may be secured.

32. A computer case as claimed in claim 30 comprising three said panels.

33. A computer case as claimed in claim 30 comprising a filtering means.

34. A computer case as claimed in claim 33 wherein said filtering means is securable to said inwardly facing surface of said panel.

35. A computer case as claimed in claim 33 wherein said filtering means is securable to said frame.

36. A computer case as claimed in claim 30 wherein the interior of said computer case is fluid communicable with the exterior of said computer case via said apertures and/or said filtering means.

37. A computer case as claimed in claim 30 comprising a panel securable to a front cover thereof.

38. A computer case as claimed in claim 30 comprising a handle means.

39. A computer comprising a computer case as claimed in claim 30.

40. A panel which may be fastened to a side, top or bottom of or formed integrally with a computer case comprising a body member defining an outwardly facing surface and an inwardly facing surface, wherein said body member is provided with at least one conglomerate of apertures, and an area defined by a perimeter of said conglomerate of apertures is at least substantially 50% of the area of the outwardly or inwardly facing surface of said body member and wherein the total area of the apertures is at least 6% of said surface of said body member.

41. A computer case comprising a panel as claimed in claim 40.

42. A computer comprising a computer case as claimed in claim 41.
